(19) United States
(12) Patent Application Publication
(10) Pub. No.: US 2026/0110091 A1
(43) Pub. Date: Apr. 23, 2026

(54) WAFER SUPPORT DEVICE AND FILM FORMING METHOD

(71) Applicants: Kabushiki Kaisha Toshiba, Kawasaki-shi (JP); Toshiba Electronic Devices & Storage Corporation, Kawasaki-shi (JP)

(72) Inventor: Tsutomu Kiyosawa, Himeji Hyogo (JP)

(21) Appl. No.: 19/364,401

(22) Filed: Oct. 21, 2025

Related U.S. Application Data
(63) Continuation of application No. PCT/JP2023/045364, filed on Dec. 18, 2023.

(30) Foreign Application Priority Data
Jul. 18, 2023 (JP) 2023-116980

(51) Int. Cl. C23C 16/458; C23C 16/32; H10P 14/60; H10P 14/69

(52) U.S. Cl. CPC C23C 16/4585; C23C 16/325; H10P 14/6334; H10P 14/6905

(57) ABSTRACT

A wafer support device according to an embodiment provides a wafer support device. The wafer support device has a support table and a wafer guide portion. The wafer guide portion includes a first chamfered portion and a second chamfered portion. The support table has a support surface that supports the wafer. The wafer guide portion has an annular shape that surrounds the circumference of the wafer supported on the support surface with the central axis extending in a normal direction of the support surface as a center. The first chamfered portion connects an inner circumferential surface and an upper surface of the wafer guide portion, and extends upward from the inner circumferential surface toward the outer circumferential side. The second chamfered portion connects an outer circumferential surface and the upper surface of the wafer guide portion, and extends upward from the outer circumferential surface toward the inner circumferential side.

### CROSS-REFERENCE TO RELATED APPLICATION

This application is a continuation application based on International Patent Application No. PCT/JP2023/045364 filed on Dec. 18, 2023, whose priority is claimed on Japanese Patent Application No. 2023-116980, filed Jul. 18, 2023. Both of the content of the PCT International Application and the Japanese Application are incorporated herein by reference.

### FIELD

Embodiments described herein relate generally to a wafer support device and a SiC epitaxial growth apparatus.

### BACKGROUND

In a wafer support device in a SiC epitaxial growth apparatus, a wafer guide is disposed around a wafer supported on a support surface. On the wafer guide, reaction products are accumulated by a SiC epitaxial growth process. In order to perform the SiC epitaxial growth process smoothly, the deposited reaction products are removed by polishing or the like to regenerate the wafer guide. When the wafer guide is subjected to the removal process at an intersection between an upper surface and a circumferential surface on which the reaction products are likely to accumulate, damage may occur.

### BRIEF DESCRIPTION OF THE DRAWINGS

FIG. 1 is a cross-sectional view showing a SiC epitaxial growth apparatus according to an embodiment.

FIG. 2 is a cross-sectional view showing a wafer support device according to the embodiment.

FIG. 3 is a partially enlarged view of FIG. 2.

FIG. 4 is a partial cross-sectional view showing the wafer support device after a SiC epitaxial growth process.

FIG. 5 is a partial cross-sectional view showing the wafer support device after the SiC epitaxial growth process.

FIG. 6 is a diagram showing an in-plane distribution of a SiC epitaxial film.

### DETAILED DESCRIPTION

A wafer support device of the embodiment is provided in a vapor phase growth apparatus. The wafer support device has a support table and a wafer guide portion. The wafer guide portion includes a first chamfered portion and a second chamfered portion. The support table has a support surface that supports a wafer. The wafer guide portion has an annular shape that surrounds a circumference of the wafer supported on the support surface with a central axis extending in a normal direction of the support surface as a center thereof. The first chamfered portion connects an inner circumferential surface and an upper surface of the wafer guide portion, and extends upward from the inner circumferential surface toward the outer circumferential side. The second chamfered portion connects an outer circumferential surface and the upper surface of the wafer guide portion, and extends upward from the outer circumferential surface toward the inner circumferential side.

Hereinafter, a wafer support device and a SiC epitaxial growth apparatus according to an embodiment will be described with reference to the drawings. In the following description, components having the same or similar functions are denoted by the same reference numerals, and duplicate descriptions thereof may be omitted.

A configuration of the SiC epitaxial growth apparatus is described below.

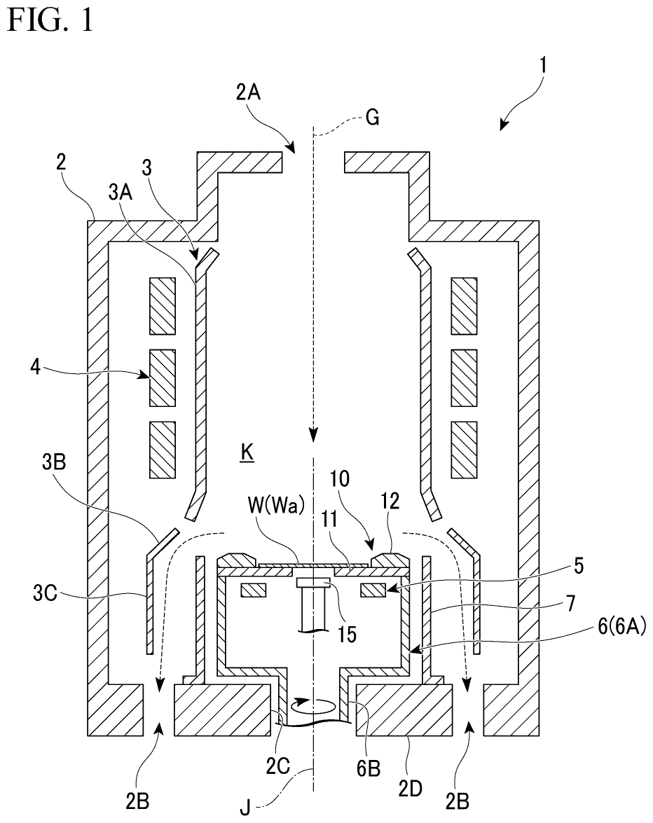

FIG. 1 is a cross-sectional view of the SiC epitaxial growth apparatus 1 having a wafer support device 10 according to an embodiment.

In the following description, the side into which a supplied source gas is introduced is referred to as the upper side, and the side from which the source gas is discharged is referred to as the lower side. In the following description, a direction along a central axis J is simply referred to as an “axial direction.” Further, a radial direction centered on the central axis J may be simply referred to as a “radial direction.” Furthermore, a circumferential direction centered on the central axis J may be simply referred to as a “circumferential direction.”

As shown in FIG. 1, the SiC epitaxial growth apparatus 1 grows an epitaxial film that will become an active region on a wafer W made of silicon carbide (SiC) by chemical vapor deposition (thermal CVD) or the like. The SiC epitaxial growth apparatus 1 includes a chamber 2, a reactor member 3, an upper heater 4, a lower heater 5, a rotating cylinder 6, a partition cylinder 7, and a wafer support device 10.

The chamber 2 is formed of a metal material such as stainless steel (SUS). The chamber 2 accommodates therein the reactor member 3, the upper heater 4, the lower heater 5, the rotating cylinder 6, the partition cylinder 7, and the wafer support device 10. The chamber 2 has an introduction port 2A, an exhaust port 2B, and an insertion port 2C. The exhaust port 2B and the insertion port 2C are provided to penetrate a bottom wall 2D of the chamber 2 in the axial direction.

The introduction port 2A is formed to open at an upper end of the chamber 2. The introduction port 2A is a portion through which gases to be used, including a source gas G, supplied from above along the central axis J, are introduced into the chamber 2. The exhaust port 2B is a portion through which the gases including the source gas G used in a SiC epitaxial growth process are exhausted.

The source gas G reacts on the wafer W to form an epitaxial film. The source gas G is, for example, a Si-based gas and a C-based gas. The Si-based gas is, for example, silane (SiH₄), dichlorosilane (SiH₂Cl₂), trichlorosilane (SiHCl₃), or tetrachlorosilane (SiCl₄). The C-based gas is, for example, propane (C₃H₈). The source gas G in the embodiment is, for example, SiH₄+C₃H₈ (flow rate: several tens to several hundreds sccm).

Other gases used besides the source gas G include impurity gas, carrier gas, and other gases. Examples of the impurity gas include N₂ (N-type impurity) and TMA (P-type impurity) (flow rate: several to several hundred sccm). Examples of the carrier gas include H₂ (during growth) and Ar (during transportation) (flow rate: 100 to 200 slm). Other gases include HCl (for curbing particles during growth, for high-speed growth) (flow rate: from several tens of sccm to several hundreds of slm).

The reactor member 3 constitutes a furnace. The reactor member 3 is made of graphite, for example. The reactor member 3 may have an inner surface coated with SiC or TaC to prevent dust generation. The reactor member 3 has a first cylindrical portion 3A, a tapered portion 3B, and a second cylindrical portion 3C.

The first cylindrical portion 3A is located on the upper side of the reactor member 3. The first cylindrical portion 3A opens below the introduction port 2A of the chamber 2. The gas containing the source gas G introduced from the introduction port 2A is introduced into an internal space of the reactor member 3. The internal space of the reactor member 3 is a film formation space K.

The tapered portion 3B extends radially outward from a lower end of the first cylindrical portion 3A downward. The second cylindrical portion 3C extends downward from a lower end of the tapered portion 3B. A radial position of the second cylindrical portion 3C is radially outward with respect to the exhaust port 2B of the chamber 2. The tapered portion 3B is disposed in a range including an axial position of a first surface Wa of the wafer W that faces upward in the up-down direction. Therefore, the gas containing the source gas G introduced from the introduction port 2A into the film formation space K flows radially outward along the first surface Wa after reaching the wafer W. The gas containing source gas G that has flowed radially outward with respect to the wafer W is guided to the tapered portion 3B and the second cylindrical portion 3C and is exhausted from the exhaust port 2B of the chamber 2.

The upper heater 4 surrounds the outer circumference of the first cylindrical portion 3A of the reactor member 3 in the circumferential direction. The upper heater 4 extends in the axial direction along the first cylindrical portion 3A. The lower heater 5 is disposed below the wafer support device 10 to be spaced apart from the wafer support device 10. The lower heater 5 has, for example, an annular shape that extends in the circumferential direction. The wafer W is heated by the upper heater 4 and the lower heater 5 to a temperature in a range of, for example, 1500 to 1650° C. The upper heater 4 and the lower heater 5 may be of known construction.

The rotating cylinder 6 is rotatable in the circumferential direction. The rotating cylinder 6 has a first rotating cylinder 6A and a second rotating cylinder 6B. The first rotating cylinder 6A is provided above the second rotating cylinder 6B. The first rotating cylinder 6A is disposed above the bottom wall 2D of the chamber 2. The lower heater 5 is disposed inside the first rotating cylinder 6A. The diameter of the first rotating cylinder 6A is larger than the diameter of the second rotating cylinder 6B. The second rotating cylinder 6B extends downward from the first rotating cylinder 6A. The second rotating cylinder 6B is inserted into the insertion port 2C.

The partition cylinder 7 is fixed to the bottom wall 2D of the chamber 2. The partition cylinder 7 extends upward in the axial direction. The partition cylinder 7 is disposed radially inward with respect to the second cylindrical portion 3C to be spaced apart radially outward from the first rotating cylinder 6A.

A configuration of the wafer support device 10 will be described below.

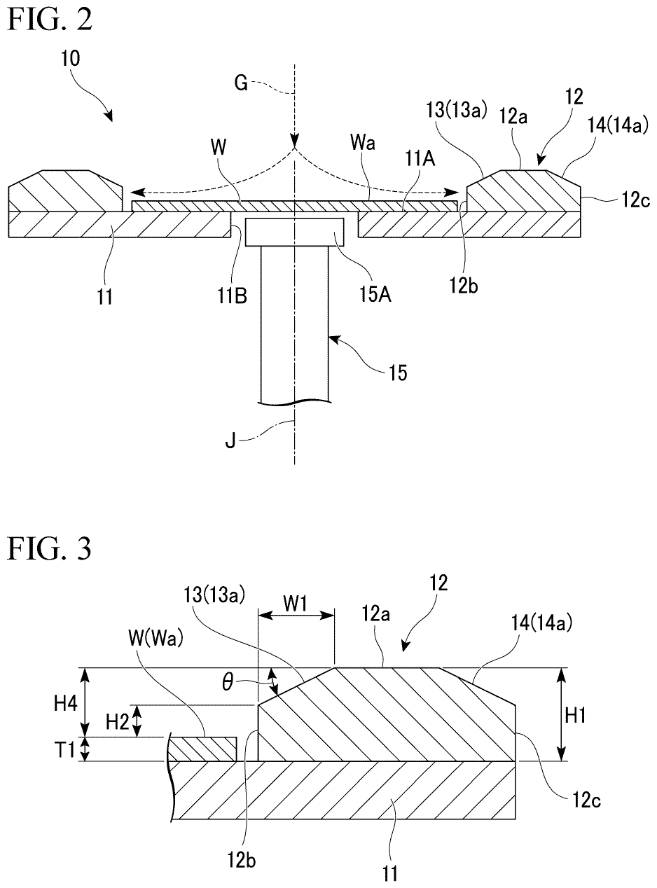

FIG. 2 is a cross-sectional view showing the wafer support device 10 of the embodiment. FIG. 3 is a partial enlarged view of FIG. 2.

As shown in FIGS. 2 and 3, the wafer support device 10 includes a support table 11, a wafer guide portion 12 including a first chamfered portion 13 and a second chamfered portion 14, and a lifting portion 15.

The support table 11 has a disk shape centered on the central axis J. The support table 11 is fixed to the first rotating cylinder 6A of the rotating cylinder 6. The support table 11 rotates in the circumferential direction by rotation of the rotating cylinder 6. The support table 11 is a susceptor. The support table 11 has a support surface 11A and a through hole 11B. The support surface 11A supports the wafer W from below on the outer side in the radial direction with respect to the through hole 11B. The through hole 11B passes through the support table 11 in the axial direction with the central axis J as a center.

The support table 11 is made of graphite, for example. The support table 11 may be coated with SiC or TaC to prevent dust generation.

The wafer guide portion 12 is disposed on a circumferential edge portion of the support table 11 to be joined from above. Although not shown in the drawings, a convex portion that protrudes from one of the support table 11 and the wafer guide portion 12 to the other is provided at a joint between the support table 11 and the wafer guide portion 12. A concave portion into which the convex portion is fitted is provided at the other of the support table 11 and the wafer guide portion 12. The wafer guide portion 12 is fixed in the radial direction to the support table 11 by fitting the convex portion and the concave portion at the joint.

The wafer guide portion 12 has an annular shape that surrounds the circumference of the wafer W supported on the support surface 11A with the central axis J extending in a normal direction of the support surface 11A as a center. The wafer guide portion 12 has a rectangular cross section, in a cross section including the central axis J, in which an intersection between an upper surface 12a and an inner circumferential surface 12b is cut away by the first chamfered portion 13. The wafer guide portion 12 has a rectangular cross section, in a cross section including the central axis J, in which an intersection between the upper surface 12a and an outer circumferential surface 12c is cut away by the second chamfered portion 14.

That is, the first chamfered portion 13 connects the inner circumferential surface 12b and the upper surface 12a of the wafer guide portion 12, and extends upward from the inner circumferential surface 12b toward the outer circumferential side. The first chamfered portion 13 has a first inclined surface 13a that inclines upward from the inner circumferential surface 12b toward the outer circumferential side in a cross section including the central axis J.

The second chamfered portion 14 connects the outer circumferential surface 12c and the upper surface 12a of the wafer guide portion 12, and extends upward from the outer circumferential surface 12c toward the inner circumferential side. The second chamfered portion 14 has a second inclined surface 14a that inclines upward from the outer circumferential surface 12c toward the inner circumferential side in a cross section including the central axis J. In other words, the first chamfered portion 13 and the second chamfered portion 14 are chamfers that extend linearly at an angle θ with respect to the upper surface 12a.

The first chamfered portion 13 may be an r-chamfer that curves and extends upward in an arc shape from the inner circumferential surface 12b toward the outer circumferential side. The second chamfered portion 14 may be an r-chamfer that curves and extends upward in an arc shape from the outer circumferential surface 12c toward the inner circumferential side.

As an example, at least the surface of the wafer guide portion 12 is made of poly-SiC. The wafer guide portion 12 may be configured to be entirely made of poly-SiC, or may be configured to be made of graphite with a SiC coating on the surface.

However, since the wafer W may move due to a centrifugal force and may collide with the wafer guide portion 12, causing the SiC coating to peel off when the wafer W is rotated via the support table 11 during an epitaxial growth process, and it is not suitable for regeneration by polishing which will be described below, it is preferable that the entire wafer guide portion 12 is formed of poly-SiC.

The lifting portion 15 is capable of moving up and down in the axial direction. The lifting portion 15 has a shaft shape that extends in the axial direction centered on the central axis J. The lifting portion 15 has a holding portion 15A having a cylindrical shape at an upper end thereof. The diameter of the holding portion 15A is smaller than the diameter of the through hole 11B in the support table 11. The holding portion 15A is disposed below the wafer W when the lifting portion 15 is in a lowered position. In other words, the lowered position of the lifting portion 15 is a position at which the holding portion 15A is below the wafer W. The holding portion 15A is separated from the wafer W when the lifting portion 15 is in the lowered position, but may be in contact with the wafer W when the wafer W is not rotating. When the lifting portion 15 is a raised position to remove the wafer W from the wafer support device 10, the holding portion 15A moves the wafer W above the support surface 11A while holding a lower surface of the wafer W.

In the SiC epitaxial growth apparatus 1 having the above-described configuration, the gas containing the source gas G introduced into the film formation space K of the reactor member 3 heated to a high temperature (for example, 1500 to 1650°C.) by the upper heater 4 and the lower heater 5 flows from the center of the wafer W to the outside in the radial direction along the first surface Wa, as indicated by a dashed line in FIG. 2.

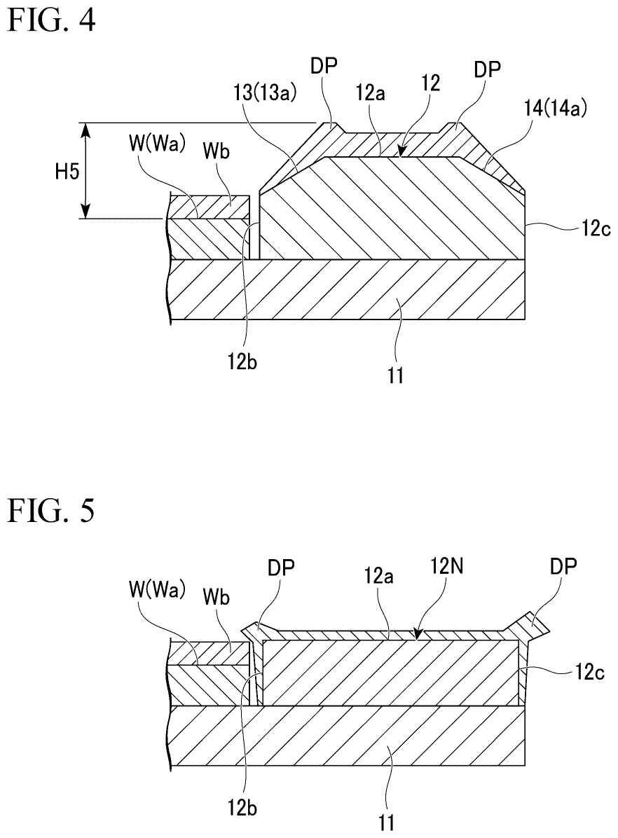

FIG. 4 is a partial cross-sectional view showing the wafer support device 10 after the SiC epitaxial growth process. By rotating the wafer W via the support table 11 while maintaining the supply of the gas containing the source gas G for a certain period of time, a SiC epitaxial film Wb is formed on the first surface Wa of the wafer W, as shown in FIG. 4. Furthermore, a deposit DP which is a reaction product accumulates on the wafer guide portion 12.

In a process of supplying a raw material of the film forming material to adhere and accumulate on the wafer W, the deposit DP is formed by the raw material that reaches the wafer guide portion 12 moving, coagulating, and accumulating due to a migration effect. At this time, when there is an inflection point in the wafer guide portion 12, it is believed that a thickness increases as the raw material slows down and becomes trapped. Therefore, in the wafer guide portion 12 having the first chamfered portion 13 and the second chamfered portion 14, the deposit DP at the intersection between the upper surface 12a and the first inclined surface 13a and the deposit DP at the intersection between the upper surface 12a and the second inclined surface 14a, which are the inflection points, grow and accumulate most thickly.

FIG. 5 is a partial cross-sectional view showing the wafer support device 10 after the SiC epitaxial growth process when a wafer guide portion 12N that does not include the first chamfered portion 13 and the second chamfered portion 14 is used.

As shown in FIG. 5, in the wafer guide portion 12N that does not include the first chamfered portion 13 and the second chamfered portion 14, the deposits DP at the intersection between the upper surface 12a and the inner circumferential surface 12b and the deposit DP at the intersection between the upper surface 12a and the outer circumferential surface 12c, which are the inflection points, grow and accumulate most thickly. The deposit DP on the wafer guide portion 12N protrudes toward the central axis J from the inner circumferential surface 12b, and protrudes radially outward from the outer circumferential surface 12c. Furthermore, even when a slight chamfering amount of about 0.1 to 0.2 mm is applied, the chamfering amount is insufficient, and the deposit DP protrudes in the radial direction.

In this case, when the wafer W is lifted using the lifting portion 15 to take the wafer W out of the wafer support device 10, the deposit DP that protrudes toward the central axis J side may come into contact with an end portion of the wafer W. Furthermore, the deposits DP that protrude radially outward with respect to the outer circumferential surface 12c, may come into contact with other members of the partition cylinder 7, and may cause scattering and dust generation, which may cause particles.

Since the wafer guide portion 12N is expensive, when the accumulation of the deposits DP becomes large, the wafer guide portion 12 is regenerated, for example, by polishing or grinding the inner circumferential surface 12b and the outer circumferential surface 12c to remove the deposits DP.

At this time, since the intersection between the upper surface 12a and the inner circumferential surface 12b and the intersection between the upper surface 12a and the outer circumferential surface 12c, which are the inflection points, are both right angles and have edge shapes, there is a possibility that defects such as cracks may occur in the wafer guide portion 12N.

On the other hand, in the wafer guide portion 12 of the wafer support device 10 of the embodiment, since the first chamfered portion 13 and the second chamfered portion 14 are provided, an intersection angle between the inner circumferential surface 12b and the first inclined surface 13a, an intersection angle between the first inclined surface 13a and the upper surface 12a, an intersection angle between the upper surface 12a and the second inclined surface 14a, and an intersection angle between the second inclined surface 14a and the outer circumferential surface 12c are all obtuse angles. Therefore, compared to the wafer guide portion 12N in which the intersection that is the inflection point has a right angle and is prone to stress concentration, in the wafer guide portion 12, since the intersection which is the inflection point has an obtuse angle, stress concentration is alleviated, and occurrence of cracks in the wafer guide portion 12 can be curbed. The wafer guide portion 12 in the wafer support device 10 of the embodiment can be regenerated while curbing the occurrence of cracks on both the inner circumferential surface 12b and the outer circumferential surface 12c.

As shown in FIG. 3, a thickness H1 of the wafer guide portion 12 in a direction along the central axis J is preferably 1.5 mm or more and 2.0 mm or less.

In a case in which the thickness H1 of the wafer guide portion 12 is less than 1.5 mm, the wafer guide portion 12 may warp when the deposit DP adheres to the upper surface 12a, and may be prone to the occurrence of cracks during the regeneration process. When the thickness H1 of the wafer guide portion 12 exceeds 2.0 mm, the wafer guide portion 12 located above the first surface Wa of the wafer W may act as a barrier and may hinder a flow of the source gas G radially outward along the first surface Wa of the wafer W.

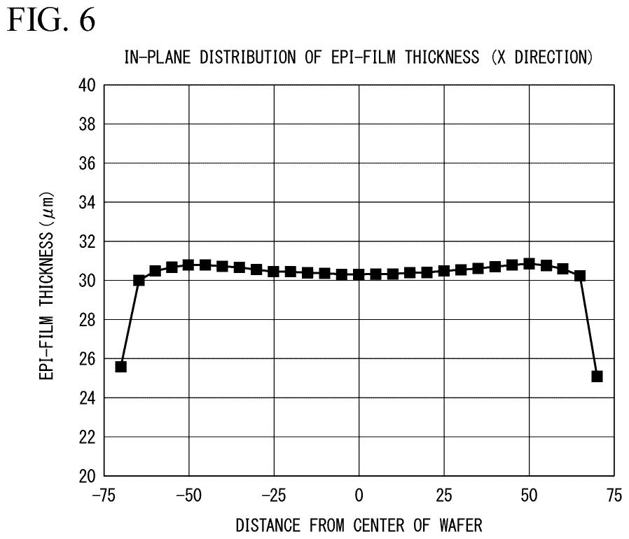

FIG. 6 is a diagram showing an in-plane distribution of the SiC epitaxial film (epi-film) Wb when the wafer guide portion 12 acts as a barrier. As shown in FIG. 6, the flow of the source gas G is hindered on the outer side in the radial direction, resulting in turbulence, which may result in a thinner film thickness of the SiC epitaxial film Wb at the circumferential edge portion of the wafer W and a deteriorated in-plane distribution. Furthermore, when the thickness T1 (for example, 300 to 600 μm) of a 6-inch or 8-inch wafer W is taken into consideration, the wafer guide portion 12 may become thicker than necessary, resulting in an increase in costs.

By setting the thickness H1 of the wafer guide portion 12 to be 1.5 mm or more and 2.0 mm or less, it is possible to reduce warping of the wafer guide portion 12 and curb cracking of the wafer guide portion 12 during the epitaxial growth process and the regeneration process while curbing the increase in costs. In addition, it is possible to curb a deterioration of the in-plane distribution of the film thickness of the SiC epitaxial film Wb.

Preferably, an angle of the first chamfered portion 13 and an angle of the second chamfered portion 14 with respect to the horizontal direction may be 10 degrees or more and 45 degrees or less.

When the angle of the first chamfered portion 13 with respect to the horizontal direction is less than 10 degrees, the intersection angle between the inner circumferential surface 12b and the first chamfered portion 13 approaches a right-angle edge shape, and thus cracks may occur in the wafer guide portion 12 during the regeneration process of the inner circumferential surface 12b. Furthermore, the deposit DP is likely to protrude toward the central axis J with respect to the inner circumferential surface 12b, an end portion of the wafer W may come into contact with the deposit DP during transportation, and thus there is a possibility of transportation failure.

Similarly, when the angle of the second chamfered portion 14 with respect to the horizontal direction is less than 10 degrees, the intersection angle between the outer circumferential surface 12c and the second chamfered portion 14 approaches a right-angle edge shape, and thus cracks may occur in the wafer guide portion 12 during the regeneration process of the outer circumferential surface 12c. Furthermore, the deposit DP is likely to protrude radially outward with respect to the outer circumferential surface 12c, may come into contact with other members of the partition cylinder 7, and may cause scattering and dust generation, which may cause particles.

Furthermore, when the angle of the first chamfered portion 13 with respect to the horizontal direction exceeds 45 degrees, the wafer guide portion 12 may act as a barrier to hinder the flow of the source gas G radially outward along the first surface Wa of the wafer W, thereby generating turbulence. In this case, as described above, there is a possibility that the in-plane distribution of the film thickness of the SiC epitaxial film Wb may deteriorate.

Therefore, by setting the angle of the first chamfered portion 13 and the angle of the second chamfered portion 14 with respect to the horizontal direction to be 10 degrees or more and 45 degrees or less, it is possible to curb the cracks in the wafer guide portion 12 during the regeneration process, the transportation failure of the wafer W, the generation of particles, and the deterioration in the in-plane distribution of the film thickness of the SiC epitaxial film Wb.

A first distance H4 in the direction along the central axis J between the first surface Wa facing upward in the wafer W and the upper surface 12a is preferably 1 mm or more and 2 mm or less.

When the first distance H4 between the first surface Wa and the upper surface 12a is less than 1 mm, and when the wafer W is warped due to high temperature, an edge of the wafer W may lift up. In this case, when the wafer W rotates via the support table 11 during the epitaxial growth process, the wafer W may move due to a centrifugal force and may jump out of the wafer guide portion 12.

When the first distance H4 between the first surface Wa and the upper surface 12a exceeds 2 mm, as described above, the flow of the source gas G will be hindered on the outer side in the radial direction, causing turbulence, which may result in the decrease in the film thickness of the SiC epitaxial film Wb and the deterioration in the in-plane distribution.

Therefore, by setting the first distance H4 between the first surface Wa and the upper surface 12a to 1 mm or more and 2 mm or less, it is possible to curb the wafer W jumping out of the wafer guide portion 12 and the deterioration of the in-plane distribution of the film thickness of the SiC epitaxial film Wb.

A second distance W1 in the radial direction centered on the central axis J between the intersection of the first chamfered portion 13 and the upper surface 12a, and the inner circumferential surface 12b is preferably 0.5 mm or more and 10 mm or less.

When the second distance W1 between the intersection of the first chamfered portion 13 and the upper surface 12a, and the inner circumferential surface 12b is less than 0.5 mm, the wafer guide portion 12 may act as a barrier and may hinder the flow of the source gas G radially outward along the first surface Wa of the wafer W, thereby generating turbulence. In this case, as described above, there is a possibility that the in-plane distribution of the film thickness of the SiC epitaxial film Wb may deteriorate.

When the second distance W1 between the intersection of the first chamfered portion 13 and the upper surface 12a, and the inner circumferential surface 12b exceeds 10 mm, since the intersection angle between the inner circumferential surface 12b and the first chamfered portion 13 approaches a right-angled edge shape, there is a possibility that cracks will occur in the wafer guide portion 12 when the inner circumferential surface 12b is reprocessed. In addition, the deposit DP is likely to protrude toward the central axis J with respect to the inner circumferential surface 12b, and there is a possibility that the wafer W may come into contact with the deposit DP during transportation, resulting in transportation failure.

Therefore, by setting the second distance W1 between the intersection of the first chamfered portion 13 and the upper surface 12a, and the inner circumferential surface 12b to 0.5 mm or more and 10 mm or less, it is possible to curb the deterioration of the in-plane distribution of the film thickness of the SiC epitaxial film Wb, the cracks in the wafer guide portion 12 during the regeneration process, and the transportation failure of the wafer W.

The position along the central axis J at which the inner circumferential surface 12b and the first chamfered portion 13 intersect is preferably above the position of the first surface Wa of the wafer W that faces upward.

When the position at which the inner circumferential surface 12b and the first chamfered portion 13 intersect is the same as or lower than the position of the first surface Wa, the wafer W may be warped due to the high temperature, and the edge of the wafer W may lift up. In this case, when the wafer W rotates via the support table 11 during the epitaxial growth process, the wafer W may move due to a centrifugal force and may jump out of the wafer guide portion 12.

Therefore, by positioning the position at which the inner circumferential surface 12b and the first chamfered portion 13 intersect above the position of the first surface Wa, it is possible to curb the wafer W jumping out of the wafer guide portion 12.

In the above-described SiC epitaxial growth process, a timing for replacing the wafer guide portion 12 due to the accumulation of the deposit DP is preferable when a maximum distance H5 in the axial direction between the first surface Wa of the wafer W and the deposit DP is 2.5 mm or less, as shown in FIG. 4.

When the maximum distance H5 between the first surface Wa of the wafer W and the deposit DP exceeds 2.5 mm, the deposit DP will accumulate too much, resulting in a large amount of work required for the regeneration process. In accordance with the accumulation state of the deposit DP, the deposit DP may protrude radially inward with respect to the inner circumferential surface 12b or radially outward with respect to the outer circumferential surface 12c.

By replacing the wafer guide portion 12 when the maximum distance H5 between the first surface Wa and the deposit DP is 2.5 mm or less, the effort required for the regeneration process of the wafer guide portion 12 can be reduced, and the transportation failure of the wafer W can be curbed.

According to at least one embodiment described above, since the first chamfered portion 13 that connects the inner circumferential surface 12b and the upper surface 12a of the wafer guide portion 12 and extends upward from the inner circumferential surface 12b toward the outer circumferential side, and the second chamfered portion 14 that connects the outer circumferential surface 12c and the upper surface 12a of the wafer guide portion 12 and extends upward from the outer circumferential surface 12c toward the inner circumferential side are provided, damage to the wafer guide portion 12 during the regeneration process can be curbed.

Furthermore, according to at least one embodiment, by setting the thickness H1 of the wafer guide portion 12 to be 1.5 mm or more and 2.0 mm or less, it is possible to curb the damage to the wafer guide portion 12 during the regeneration process and the deterioration of the in-plane distribution of the film thickness of the SiC epitaxial film Wb while curbing the increase in costs.

Furthermore, according to at least one embodiment, by setting the angle of the first chamfered portion 13 and the angle of the second chamfered portion 14 with respect to the horizontal direction to 10 degrees or more and 45 degrees or less, it is possible to curb the damage to the wafer guide portion 12 during the regeneration process, the transportation failure of the wafer W, the generation of particles, and the deterioration of the in-plane distribution of the film thickness of the SiC epitaxial film Wb.

Furthermore, according to at least one embodiment, by setting the first distance H4 between the first surface Wa and the upper surface 12a to 1 mm or more and 2 mm or less, it is possible to curb the wafer W jumping out of the wafer guide portion 12 and the deterioration of the in-plane distribution of the film thickness of the SiC epitaxial film Wb.

Furthermore, according to at least one embodiment, by setting the second distance W1 between the intersection of the first chamfered portion 13 and the upper surface 12a, and the inner circumferential surface 12b to 0.5 mm or more and 10 mm or less, it is possible to curb the deterioration of the in-plane distribution of the film thickness of the SiC epitaxial film Wb, the damage to the wafer guide portion 12 during the regeneration process, and the transportation failure of the wafer W.

Furthermore, according to at least one embodiment, by positioning the position at which the inner circumferential surface 12b and the first chamfered portion 13 intersect above the position of the first surface Wa, it is possible to curb the wafer W jumping out of the wafer guide portion 12.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A wafer support device provided in a vapor phase growth apparatus, comprising:
a support table having a support surface configured to support a wafer; and
a wafer guide portion having an annular shape and configured to surround a circumference of the wafer supported on the support surface with a central axis that extends in a normal direction of the support surface as a center, wherein the wafer guide portion comprises:
a first chamfered portion configured to connect an inner circumferential surface and an upper surface of the wafer guide portion and configured to extend upward from the inner circumferential surface toward an outer circumferential side; and
a second chamfered portion configured to connect an outer circumferential surface and the upper surface of the wafer guide portion and configured to extend upward from the outer circumferential surface toward an inner circumferential side,
wherein, in a cross section including the central axis, the first chamfered portion has a first inclined surface that is inclined upward from the inner circumferential surface toward the outer circumferential side,
in the cross section, the second chamfered portion has a second inclined surface that is inclined upward from the outer circumferential surface toward the inner circumferential side,
a second distance in a radial direction centered on the central axis between an intersection of the first chamfered portion and the upper surface, and the inner circumferential surface is 0.5 mm or more and 10 mm or less,
a position in a direction along the central axis at which the inner circumferential surface and the first chamfered portion intersect is above a position of a first surface of the wafer that faces upward, and
an angle of the first chamfered portion and an angle of the second chamfered portion with respect to a horizontal direction are 10 degrees or more and 45 degrees or less.

2. The wafer support device of claim 1, wherein a thickness between an upper surface and a lower surface of the wafer guide portion in a direction along the central axis is 1.5 mm or more and 2.0 mm or less.

3. The wafer support device of claim 1, wherein a first distance between a first surface that faces upward in the wafer and the upper surface in a direction along the central axis is 1 mm or more and 2 mm or less.

4. The wafer support device of claim 1, wherein at least a surface of the wafer guide portion is made of poly-SiC.

5. A SiC epitaxial growth apparatus comprising the wafer support device of claim 1.

6. A film forming method for forming a film on a surface of a wafer using a vapor phase growth apparatus equipped with the wafer support device of claim 1, comprising:
a film forming process of forming the film on the surface of the wafer,
wherein a reaction product generated by vapor phase growth is formed on the wafer guide portion during the film forming process, and
the reaction product is deposited increasingly thickly in a direction away from the upper surface in the normal direction at an intersection of the upper surface and the first inclined surface or an intersection of the upper surface and the second inclined surface that forms an inflection point.
